(19) United States
(12) Patent Application Publication
(10) Pub. No.: US 2026/0269150 A1
(43) Pub. Date: Sep. 10, 2026

(54) SPACER FOR FRONT ACCESS CIRCUIT BREAKERS

(71) Applicant: Vertiv Corporation, Westerville, OH (US)

(72) Inventors: Omkar Suresh Vichare, Ratnagiri (IN); Kishan Jaysukh-Bhai Jethva, Pune (IN)

(21) Appl. No.: 19/559,311

(22) Filed: Mar. 6, 2026

(30) Foreign Application Priority Data
Mar. 6, 2025 (IN) 202511020256

(51) Int. Cl. H01H 9/52; H01H 9/02; H05K 7/20

(52) U.S. Cl. CPC H01H 9/52; H01H 9/02; H05K 7/2039

(57) ABSTRACT

The present disclosure relates to a spacer for circuit breaker. The spacer for a circuit breaker, comprising a cuboidal enclosure having a plurality of surfaces forming a space for mounting over a top of the circuit breaker with one or more adjacent circuit breakers. The plurality of surfaces includes a first surface having a plurality of cutouts for dissipation of heat from the circuit breaker, a second surface having an open slot for allowing connection of wires. Further, a third open surface and a fourth open surface are provided, which form the space within the enclosure for mounting over the top of the circuit breaker. Further, a fifth surface and a sixth surface is provided which are opposite to each other and having a thickness to provide an air gap with the one or more adjacent circuit breakers.

### CROSS-REFERENCE TO RELATED APPLICATIONS

The present application claims the benefit under 35 U.S.C. § 119(e) of Indian Provisional Patent Application Serial Number 202511020256 filed Mar. 6, 2025, which is incorporated herein by reference in the entirety.

### TECHNICAL FIELD

The present disclosure generally relates to circuit breaker spacers in power systems. More specifically, the present disclosure relates to a spacer mountable on front access circuit breakers, providing heat dissipation and acting as a supporting member for the circuit breakers in the shelves of the power systems.

### BACKGROUND

The subject matter discussed in the background section should not be assumed to be prior art merely as a result of its mention in the background section. Similarly, a problem mentioned in the background section or associated with the subject matter of the background section should not be assumed to have been previously recognized in the prior art.

Circuit breakers are essential components in electrical systems, providing protection by interrupting electrical flow during faults or short circuit scenarios. Typically, in a direct current (DC) power system panels, multiple circuit breakers are arranged adjacent to one another on a shelf. Typically, existing DC power systems are fitted with fixed-sized circuit breakers, which are separated by spacers mounted on metal sheets of the shelf. In the state of the art, spacers are used between the circuit breakers, which are made from insulating materials, and these spacers serve the purpose of keeping the circuit breakers separated from each other and at the same time, insulating electrical contacts.

However, existing spacers may not effectively address the problem of accommodating different sizes of circuit breakers. Fixed mounting of front Access circuit breakers in the DC power system causes issues, leading to restricted breaker sizes. Further, existing spacers engaged with the circuit breakers have chances of deformation due to exposure to bus bar heat. Further, existing spacers are not firmly fixed on the base metal sheet, resulting in instability of breakers in the DC power system. Therefore, under certain conditions, such as high currents, the spacers themselves may become a point of failure. The heat generated by the passage of current can cause the spacers to degrade or lose their insulating properties, potentially leading to short circuits or even failure of the circuit breaker assembly.

Therefore, a universal spacing solution is needed to allow different sizes of breakers and reduce complexity. Given the above-mentioned challenges and the limitations of current solutions, there is a need for a spacer that provides both ease of installation and improved heat dissipation, and acts as a supporting member for circuit breakers in the shelf.

### SUMMARY OF THE INVENTION

This summary is provided to introduce aspects related to a spacer for front access circuit breakers in power systems, and the aspects are further described below in the detailed description. This summary is not intended to identify essential features of the present subject matter, nor is it intended for use in determining or limiting the scope of the present subject matter.

In an embodiment of the present invention, a spacer for a circuit breaker is disclosed. The spacer for a circuit breaker comprises a cuboidal enclosure having a plurality of surfaces forming an open space for mounting over the top of a front access circuit breaker with one or more adjacent circuit breakers. The plurality of surfaces includes a first surface having a plurality of cutouts for dissipation of heat from the circuit breaker, a second surface having an open slot for allowing connection of wires, a third surface, and a fourth surface forming the open space within the enclosure for mounting over the top of the front access circuit breaker. Further, a fifth surface and a sixth surface are provided, which are opposite to each other and have a thickness to provide an air gap with one or more adjacent circuit breakers.

In an embodiment of the present invention, the spacer is made of polycarbonate material.

In an embodiment, the enclosure formed by the plurality of surfaces of the spacer is cuboidal in shape.

In an embodiment, the plurality of cutouts on the first surface is selected from any one of hexagonal perforations, circular perforations, square perforations, rectangular perforations, or triangular perforations.

In one embodiment, the spacer is mounted on the alternate circuit breakers in a row.

In an embodiment, the width of the fifth surface and the sixth surface is 3 mm, respectively.

In another embodiment, the fifth surface and the sixth surface of the spacer provide a gap of 3mm between the adjacent circuit breakers.

In yet another embodiment, the spacer is formed from an electrically insulating plastic material.

In an embodiment, the first surface of the spacer acts as a supporting member for a top shelf.

In yet another embodiment, the length and width of the surfaces of the spacer vary depending upon the size of the circuit breaker upon which the spacer would be mounted.

In another embodiment of the present invention, a spacer for a front-access circuit breaker mounted in a power system panel is disclosed. In one or more embodiments, the spacer includes: an electrically insulating, unitary enclosure configured to be detachably mounted directly over a top of the circuit breaker, the enclosure including: adjacent open end surfaces including a bottom open end surface and a rear open end surface, wherein the adjacent open end surfaces define an internal space sized to receive the circuit breaker; a top surface opposite of the bottom open end surface including a plurality of perforations configured to dissipate heat from the circuit breaker; a front surface extending from the top surface and opposite the rear open surface, wherein the front surface includes an opening configured to permit electrical wiring access to the circuit breaker while the spacer remains mounted, and opposed side surfaces extending from the top surface.

In another embodiment of the present invention, a spacer for a front-access circuit breaker mounted in a power system panel is disclosed. In one or more embodiments, the spacer includes: an electrically insulating, unitary enclosure formed from a heat-resistant polycarbonate material, the enclosure being cuboidal in shape and configured to be detachably mounted directly over a top of the circuit breaker while the circuit breaker remains installed in the power system panel, the enclosure including: a bottom open end surface and a rear open end surface adjacent to one another and defining an internal space sized to receive the circuit breaker; a top surface opposite the bottom open end surface, the top surface including a plurality of perforations selected from hexagonal, circular, square, rectangular, or triangular perforations, the perforations being configured to dissipate heat from the circuit breaker, the top surface further being configured to contact and support an upper shelf of the power system panel; a front surface extending from the top surface and opposite the rear open end surface, the front surface including an opening configured to permit electrical wiring access to the circuit breaker while the spacer remains mounted; and opposed side surfaces extending from the top surface, each opposed side surface having a thickness of approximately 3 mm, wherein the spacer is configured to be slid over the circuit breaker through the bottom open end surface and the rear open end surface.

Other aspects and advantages of the invention will become apparent from the following description, taken in conjunction with the accompanying drawings, illustrating by way of example the principles of the invention.

### BRIEF DESCRIPTION OF THE DRAWINGS

The accompanying figures of the drawing, which are included to provide a further understanding of general aspects of the system/method, are incorporated in and constitute a part of this specification. These illustrative aspects of the system/method, together with the detailed description, explain the principles of the system. No attempt is made to show structural details in more detail than is necessary for a fundamental understanding of the system and various ways in which it is practiced.

FIG. 1 illustrates the state-of-the-art mounting of circuit breakers in a DC power system, according to the prior art.

FIG. 2 illustrates a sectional view of the sheet metal cutout for installation of the state of the spacers, according to the prior art.

FIG. 3 illustrates a perspective view of a spacer mountable on the circuit breakers.

FIG. 4 illustrates a perspective view of the spacer mounted on the circuit breaker.

FIG. 5 illustrates a front view of a series of circuit breakers installed within the DC power system with a mounted spacer.

FIG. 6 illustrates a front view of a series of circuit breakers in the DC power system with a gap between the top and bottom shelves.

In the appended figures, similar components and/or features may have the same numerical reference label. Further, various components of the same type may be distinguished by following the reference label with a letter. If only the first numerical reference label is used in the specification, the description is applicable to any one of the similar components and/or features having the same first numerical reference label, irrespective of the suffix.

### DETAILED DESCRIPTION OF THE INVENTION

Illustrative embodiments are described with reference to the accompanying drawings. Wherever convenient, the same reference numbers are used throughout the drawings to refer to the same or similar parts. While examples and features of disclosed principles are described herein, modifications, adaptations, and other implementations are possible without departing from the spirit and scope of the disclosed embodiments. It is intended that the following detailed description be considered as exemplary only, with the true scope and spirit being indicated by the following claims.

Circuit breakers are primary components in Alternating current (AC) and direct current (DC) power systems and protect from sudden surges in current or short circuits. In a typical scenario, the DC power system panel has a predetermined way of accommodating circuit breakers, and a spacer is arranged between the circuit breaker for insulation purposes.

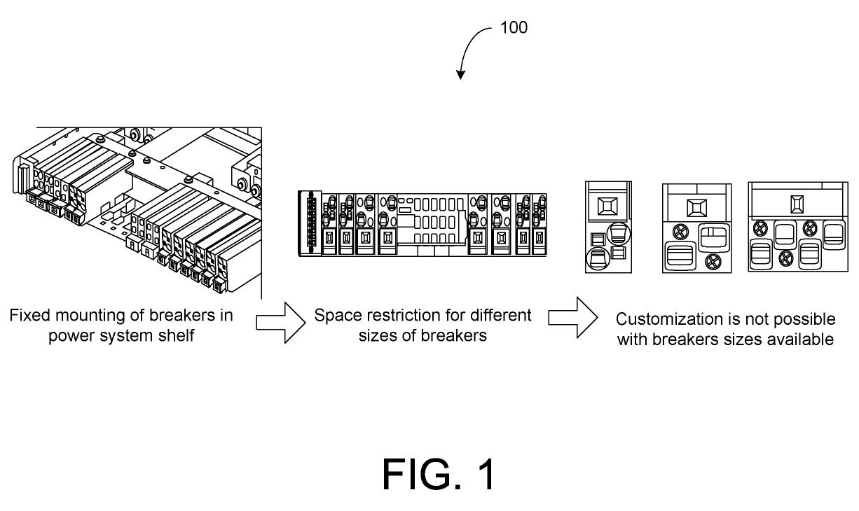

FIG. 1 illustrates the state-of-the-art mounting of circuit breakers 100 in a DC power system, according to the prior art. As illustrated, one drawback associated with current DC power systems is that the system uses different types of circuit breakers according to their Ampere rating. Permanent Placement of these circuit breakers in the system makes manufacturing more complex, and a customer may not be able to use different sizes of breakers. For example, if the customer requires a 63 Amp circuit breaker instead of a 125 Amp breaker, with permanent placement, this will be impossible to change as the sizes are different. The existing spacers do not support changing the circuit breaker sizes. Existing spacers may not effectively address the problem of accommodating different sizes of breakers.

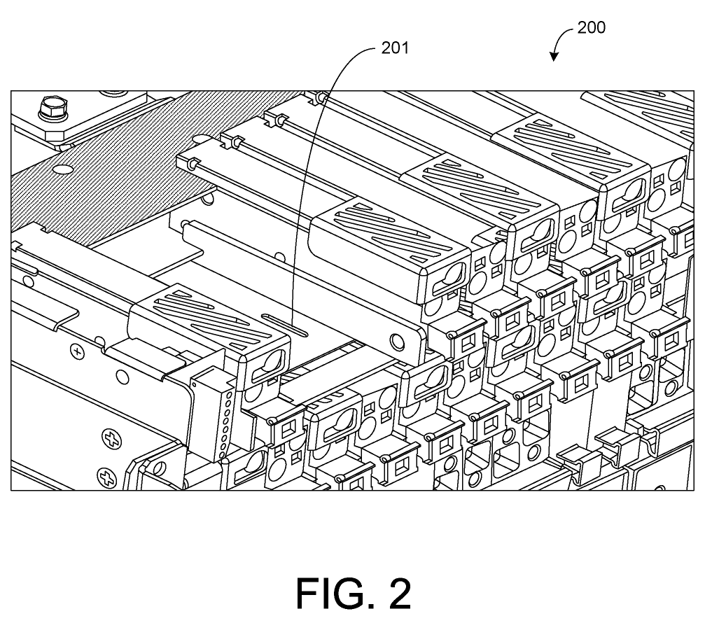

FIG. 2 illustrates a sectional view of the shelf 200 with sheet metal cutout 201 for installation of conventional spacers, according to the prior art. Existing spacers are engaged with the shelf via a sheet metal cutout, and such spacers are prone to deformation or damage due to bus bar heat exposure. Further, existing spacers are not firmly fixed on the base, resulting in instability of breakers in the DC power system. Further, providing metal cutouts also weakens the strength of the metal sheet of the shelf.

Therefore, the present invention provides an improved spacer for circuit breakers that achieves multiple purposes, for example, proper alignment of circuit breakers, different sizes of spacers for different circuit breaker sizes, thereby enabling accommodation of circuit breakers of different sizes yet aligned in tight arrangements with an appropriate air gap for ventilation.

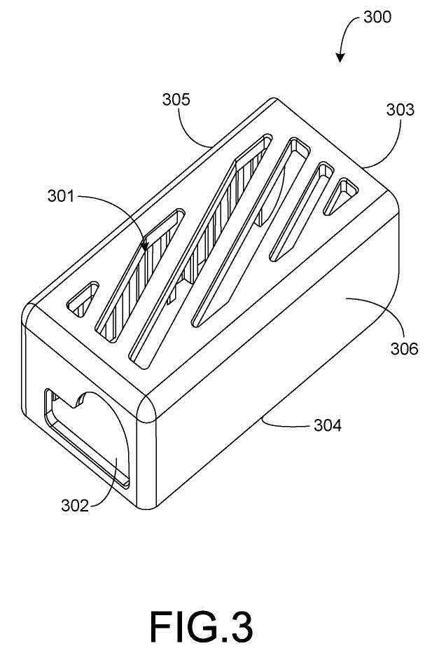

FIG. 3 illustrates a perspective view of a spacer 300 mountable on the circuit breakers. The spacer 300 for the circuit breaker comprises a unitary enclosure having a plurality of surfaces 301, 302, 303, 304, 305, 306 forming an open space for mounting over a top of the circuit breaker. The length and width of the surfaces 301, 302, 303, 304, 305, 306 may vary depending upon the size of the circuit breaker upon which the spacer would be mounted or fitted. In an embodiment, the enclosure formed by the plurality of surfaces 301, 302, 303, 304, 305, and 306 is cuboidal in shape. The spacer, when mounted over circuit breaker, the inner side of surfaces 301, 302, 305, 306 are in close contact with the circuit breaker.

In the plurality of surfaces, the surface 301 may be referred to as a first surface or top surface, the surface 302 may be referred to as a second surface or front surface that extends from the top surface. The surface 303, 304 may be referred to as a third open surface (e.g., rear open end surface) and a fourth open surface (e.g., bottom open end surface), respectively. The surfaces 305, 306 may be referred to as a fifth surface 305 and a sixth surface 306, respectively, or may be referred to as opposed side surfaces.

In an embodiment, the third open surface 303 and the fourth open surface 304 form a space within the enclosure for mounting over the top of the circuit breaker and/or define an internal space sized to receive the circuit breaker. In another embodiment, the first surface 301 of the spacer has a plurality of cutouts which help dissipate heat when the spacer is mounted on the circuit breaker. In an embodiment, the plurality of cutouts on the first surface 301 is selected from any one of hexagonal perforations, circular perforations, square perforations, rectangular perforations, or triangular perforations. Further, the first surface 301 of the spacer acts as a supporting member for a top shelf.

In yet another embodiment, the second surface 302 has an open slot for allowing or permitting connection of wires to the circuit breakers. In an embodiment, the fifth surface 305 and the sixth surface 306 are opposite to each other (extend from the first surface 301) and have a thickness for providing an air gap with one or more adjacent circuit breakers. In an embodiment, the width of the fifth surface 305 and the sixth surface 306 is in the range of 1-3 mm, respectively. When the spacer is mounted on the alternate circuit breakers in a row, the fifth surface 305 and a sixth surface 306 of the spacer provide a gap in the range of 1-3mm between the adjacent circuit breakers. In a preferred embodiment, the width of the fifth surface 305 and the sixth surface 306 is substantially or approximately 3mm, thereby providing a gap of substantially or approximately 3mm between the adjacent circuit breakers.

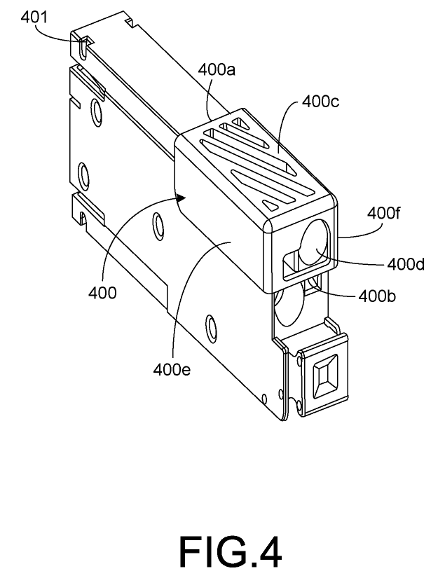

In an embodiment, the spacer is formed from an electrically insulating plastic material, for example, polycarbonate, which is resistant to heat. A more detailed embodiment of a spacer mounted on the circuit breaker is illustrated in reference to FIG. 4.

FIG. 4 illustrates a perspective view of a circuit breaker 401 mounted with a spacer 400, according to an exemplary embodiment. In an embodiment, the spacer 400 is a cuboidal enclosure with open surfaces 400a and 400b, which enables a user or customer to detachably mount the spacer 400 over top of a circuit breaker 401. In an embodiment, the circuit breakers are front-access circuit breakers, and the spacer is slid over the circuit breaker 401 through the open surfaces 400a and 400b. In another embodiment, the circuit breaker may be removed from the power system panel, the spacer 400 is mounted on the circuit breaker 401 through the open surfaces 400a and 400b. Once the spacer 400 is rigidly mounted on the circuit breaker 401, the circuit breaker is placed back on the power system panel.

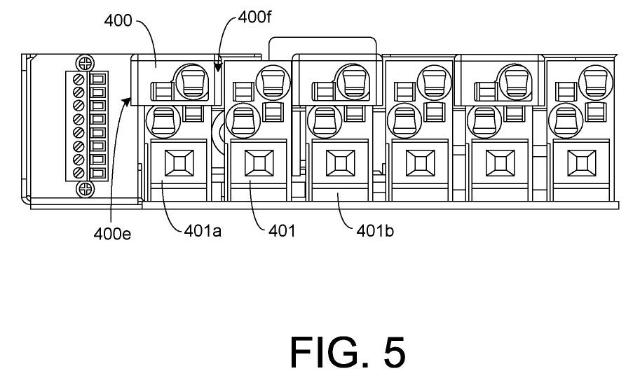

In an embodiment, surfaces 400c, 400d, 400e, and 400f are in close contact with the circuit breaker. It is necessary to have a mechanism to dissipate heat from the circuit breakers, and the spacer 400 provides a provision for dissipation of heat through a plurality of cut-outs on the surface 400c. The cutouts on the surface 400c help dissipation of heat from the surface of the circuit breaker 401. As the circuit breaker, in an embodiment, is a front access breaker, the surface 400d of the spacer 400 provides an opening for connection of wires with the circuit breakers. The opening on the surface 400d provides the ease of changing or fixing the wiring on the circuit breaker. In a further embodiment, the surfaces 400e and 400f have a predetermined thickness, which helps in providing an air gap with the alternative circuit breakers, embodiments of which are illustrated with reference to FIG. 5.

FIG. 5 illustrates a front view of a series of circuit breakers installed within the DC power system with a mounted spacer, according to an embodiment of the present invention. In a power system panel, such as DC power system panels, a number of circuit breakers 401, 401a, 401b are arranged in series, in a tight arrangement. According to the present invention, the spacer 400 is mounted on alternate circuit breakers. As mentioned above, the surfaces 400e, 400f of the spacer 400 have a predetermined thickness, which helps in providing an air gap (for example 3mm gap) with the side surface of alternative circuit breakers on both sides. The air gap helps in the dissipation of heat from the power panels, resulting in increased efficiency in thermal management in panels without any additional components. In an embodiment, the circuit breakers are front-access circuit breakers, and the spacer 400 slides over the circuit breaker 401 through the open surfaces 400a and 400b. In another embodiment, the circuit breaker may be removed from the power system panel, and the spacer 400 is mounted on the circuit breaker 401 through the open surfaces 400a and 400b. Once the spacer 400 is rigidly mounted on the circuit breaker 401, the circuit breaker is placed back on the power system panel in a tight arrangement with other circuit breakers.

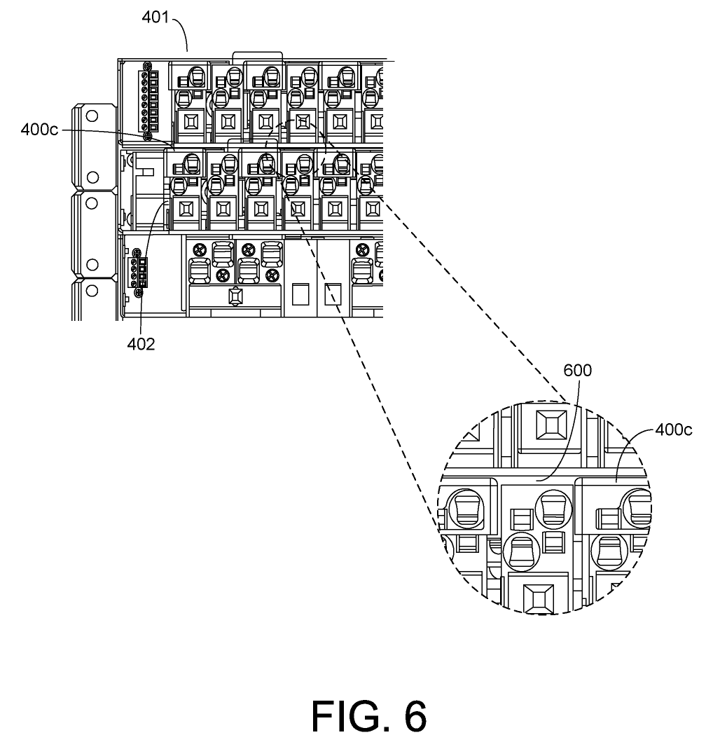

FIG. 6 illustrates a front view of a shelf with a series of circuit breakers arranged in the DC power system with a gap between the top and bottom shelves, according to another embodiment of the present invention. In an embodiment, a series of circuit breakers 401, 402 may be arranged in top and bottom shelves. As illustrated, the spacers are arranged on alternate circuit breakers, wherein the surface 400c provides contact with the upper shelf. In an embodiment, the material of the spacer is made up of polycarbonate materials, making it heat-resistant. This arrangement provides an advantage wherein the surface 400c has a thickness which provides or establishes an air gap 600 between the upper shelf surface and the top surface of the alternate circuit breaker (without a spacer). This feature provides further air ventilation to heat dissipation thereby creating the thermal efficiency of the power systems.

The present invention provides a spacer that is mountable on the circuit breakers and provides structural stability to the breaker within the shelf. Further, the surfaces of the spacers provide enhanced heat dissipation, thereby improving thermal management of the DC panels. Further, a spacer’s size is variable and enables the mounting of circuit breakers of different sizes without making changes to the shelf structure.

The systems and devices discussed herein are examples. Various embodiments may omit, substitute, or add various procedures or components as appropriate. For instance, in alternative embodiments, the methods may be performed in an order different from that described, and/or various stages may be added, omitted, and/or combined. Also, features described with respect to certain embodiments may be combined in various other embodiments. Different aspects and elements of the embodiments may be combined in a similar manner. Also, technology evolves and, thus, many of the elements are examples and do not limit the scope of the disclosure or claims. Additionally, the techniques discussed herein may provide differing results with different types of context awareness classifiers.

Unless defined otherwise, all technical and scientific terms used herein have the same meaning as commonly or conventionally understood. As used herein, the articles “a” and “an” refer to one or to more than one (i.e., to at least one) of the grammatical object of the article. By way of example, “an element” means one element or more than one element. “About” and/or “approximately” as used herein when referring to a measurable value such as an amount, a temporal duration, and the like, encompasses variations of +20% or +10%, +5%, or +0.1% from the specified value, as such variations are appropriate to in the context of the systems, devices, circuits, methods, and other implementations described herein. “Substantially” as used herein when referring to a measurable value such as an amount, a temporal duration, a physical attribute (such as frequency), and the like, also encompasses variations of ±20% or ±10%, ±5%, or ±0.1% from the specified value, as such variations are appropriate to in the context of the systems, devices, circuits, methods, and other implementations described herein.

As used herein, including in the claims, “and” as used in a list of items prefaced by “at least one of” or “one or more of” indicates that any combination of the listed items may be used. For example, a list of “at least one of A, B, and C” includes any of the combinations A or B or C or AB or AC or BC and/or ABC (i.e., A and B and C). Furthermore, to the extent that more than one occurrence or use of the items A, B, or C is possible, multiple uses of A, B, and/or C may form part of the contemplated combinations. For example, a list of “at least one of A, B, and C” may also include AA, AAB, AAA, BB, etc.

While illustrative and presently preferred embodiments of the disclosed systems, methods, and/or machine-readable media have been described in detail herein, it is to be understood that the inventive concepts may be otherwise variously embodied and employed, and that the appended claims are intended to be construed to include such variations, except as limited by the prior art. While the principles of the disclosure have been described above in connection with specific apparatuses and methods, it is to be clearly understood that this description is made only by way of example and not as a limitation on the scope of the disclosure.

What is claimed is:

1. A spacer for a circuit breaker, comprising:
an enclosure having a plurality of surfaces forming a space for mounting over a top of the circuit breaker with one or more adjacent circuit breakers, wherein the plurality of surfaces includes:
a first surface having a plurality of cutouts for dissipation of heat from the circuit breaker;
a second surface having an open slot for allowing connection of wires;
a third open surface and a fourth open surface forming the space within the enclosure for mounting over the top of the circuit breaker; and
a fifth surface and a sixth surface, wherein the fifth and sixth surface are opposite to each other and having a thickness to provide an air gap with the one or more adjacent circuit breakers.

2. The spacer of claim 1, wherein the enclosure formed by the plurality of surfaces is cuboidal in shape.

3. The spacer of claim 1, wherein the plurality of cutouts on the first surface is selected from any one of hexagonal perforations, circular perforations, square perforations, rectangular perforations, or triangular perforations.

4. The spacer of claim 1, wherein a plurality of spacers are mountable on alternate circuit breakers in a row of circuit breakers, wherein mounting the plurality of spacers on alternative circuit breakers creates an air gap between the row of circuit breakers and an upper shelf of circuit breakers.

5. The spacer of claim 4, wherein a width of the fifth surface and the sixth surface is approximately 3 mm, respectively.

6. The spacer of claim 5, wherein the fifth surface and a sixth surface of the spacer provide a gap of approximately 3mm between the adjacent circuit breakers.

7. The spacer of claim 1, wherein the spacer is formed from an electrically insulating plastic material.

8. The spacer of claim 1, wherein the first surface of the spacer acts as a supporting member for a top shelf.

9. The spacer of claim 1, wherein a length and a width of the surfaces vary depending upon a size of the circuit breaker upon which the spacer would be mounted.

10. The spacer of claim 1, wherein inner surfaces of the plurality of surfaces are in close contact with the circuit breaker.

11. The spacer of claim 1, wherein the spacer is configured to slide over the circuit breaker via the third open surface and the fourth open surface.

12. A spacer for a front-access circuit breaker mounted in a power system panel, comprising:
an electrically insulating, unitary enclosure configured to be detachably mounted directly over a top of the circuit breaker, the enclosure comprising:
adjacent open end surfaces comprising a bottom open end surface and a rear open end surface, wherein the adjacent open end surfaces define an internal space sized to receive the circuit breaker;
a top surface opposite of the bottom open end surface comprising a plurality of perforations configured to dissipate heat from the circuit breaker;
a front surface extending from the top surface and opposite the rear open surface, wherein the front surface comprises an opening configured to permit electrical wiring access to the circuit breaker while the spacer remains mounted, and
opposed side surfaces extending from the top surface.

13. The spacer of claim 12, wherein the top surface is configured to contact and support an upper shelf of the power system panel.

14. The spacer of claim 12, wherein the opposed side surfaces comprise a predetermined thickness selected to establish a fixed air gap between the circuit breaker and adjacent circuit breakers when the spacer is mounted on alternate circuit breakers in a row.

15. The spacer of claim 12, wherein the spacer enables installation of circuit breakers of different sizes in a same panel without modification of a shelf structure while improving thermal dissipation and mechanical stability.

16. The spacer of claim 12, wherein the electrically insulating, unitary enclosure is formed from a heat‑resistant polycarbonate material.

17. The spacer of claim 12, wherein each of the opposed side surfaces has a thickness in a range of approximately 1 mm to approximately 3 mm.

18. The spacer of claim 12, wherein the spacer is configured to be slid over the circuit breaker through the bottom open end surface and the rear open end surface while the circuit breaker remains installed in the power system panel.

19. A spacer for a front-access circuit breaker mounted in a power system panel, the spacer comprising: an electrically insulating, unitary enclosure formed from a heat-resistant polycarbonate material, the enclosure being cuboidal in shape and configured to be detachably mounted directly over a top of the circuit breaker while the circuit breaker remains installed in the power system panel, the enclosure comprising:
a bottom open end surface and a rear open end surface adjacent to one another and defining an internal space sized to receive the circuit breaker;
a top surface opposite the bottom open end surface, the top surface comprising a plurality of perforations selected from hexagonal, circular, square, rectangular, or triangular perforations, the perforations being configured to dissipate heat from the circuit breaker, the top surface further being configured to contact and support an upper shelf of the power system panel;
a front surface extending from the top surface and opposite the rear open end surface, the front surface comprising an opening configured to permit electrical wiring access to the circuit breaker while the spacer remains mounted; and
opposed side surfaces extending from the top surface, each opposed side surface having a thickness of approximately 3 mm, wherein the spacer is configured to be slid over the circuit breaker through the bottom open end surface and the rear open end surface.

20. The spacer of claim 19, wherein when a plurality of the spacers are mounted on alternate circuit breakers in a row of front-access circuit breakers, the opposed side surfaces establish a fixed air gap of approximately 3 mm between adjacent circuit breakers, thereby improving thermal dissipation and mechanical stability without modification of a shelf structure.
